(19) United States
(12) Patent Application Publication
(10) Pub. No.: US 2024/0363570 A1
(43) Pub. Date: Oct. 31, 2024

(54) INTEGRATED CIRCUITS WITH CONDUCTIVE POSTS HAVING ROUGH SIDEWALLS

(71) Applicant: Texas Instruments Incorporated, Dallas, TX (US)

(72) Inventors: Jose Daniel Carlos Torres, Angeles City (PH); Katleen Fajardo Timbol, Allen, TX (US)

(21) Appl. No.: 18/141,456

(22) Filed: Apr. 30, 2023

(51) Int. Cl. H01L 23/00

(52) U.S. Cl. CPC H01L 24/13; H01L 24/03; H01L 24/05; H01L 24/11; H01L 24/16; H01L 23/31; H01L 23/4951; H01L 2224/03614; H01L 2224/03912; H01L 2224/05022; H01L 2224/05124; H01L 2224/05562; H01L 2224/05582; H01L 2224/05647; H01L 2224/05655; H01L 2224/05666; H01L 2224/05672; H01L 2224/0568; H01L 2224/05681; H01L 2224/05684; H01L 2224/11462; H01L 2224/11464; H01L 2224/11831; H01L 2224/13018; H01L 2224/13147; H01L 2224/16245

(57) ABSTRACT

A semiconductor package comprises an integrated circuit having a contact and a conductive bump directly attached to the contact. The conductive bump has a sidewall with a roughened surface. A leadframe is electrically coupled to the conductive bump. An integrated circuit package mold covers portions of the conductive bump and the lead frame, the roughened surface of the conductive bump is configured to interlock with the integrated circuit package mold. An electrically conductive adhesive couples the conductive bump to the lead frame. The conductive bump comprises copper in one arrangement. The roughened surface of the conductive bump includes grooves along grain boundaries that separate copper grains. The roughened surface of the conductive bump is formed by etching with a diluted sulfuric peroxide solution.

### BACKGROUND

Typically, integrated circuit packages, such as integrated circuits for high current power applications, include conductive bumps on an integrated circuit (IC) die to provide electrical connections between a leadframe and contacts the integrated circuit die. A mold compound is applied to surround the conductive bumps, IC die, and leadframe. The mold compound provides protection to the integrated circuit.

Semiconductor packaging techniques have evolved to accommodate smaller chip sizes that are made possible by technological advances and to provide increased power dissipation and power density. Flip chip on leadframe (FCOL) packaging technologies provide efficient use of space for small outline transistor (SOT) and quad flat no-lead (QFN) packages. FCOL packages eliminating wire-bond interconnections, which achieves benefits such as reduced interconnection inductance and resistance, greater utilization of the package-to-die area, and improved input/output and interconnect density. An FCOL package has a bumped IC die that is mounted directly onto a leadframe and then overmolded. In some applications, the mold compound easily delaminates from the smooth bare finish of the conductive bumps, which can cause polyimide (PI) cracks and solder cracks in the FCOL package. These cracks result in Drain to Source On Resistance (R_{DS(on)}) shift or continuity failures in the affected packages.

### SUMMARY

In an arrangement, a semiconductor package comprises an integrated circuit having a contact and a conductive bump directly attached to the contact. The conductive bump has a sidewall with a roughened surface. A leadframe is electrically coupled to the conductive bump. An integrated circuit package mold covers portions of the conductive bump and the lead frame, the roughened surface of the conductive bump is configured to interlock with the integrated circuit package mold. An electrically conductive adhesive couples the conductive bump to the lead frame. The conductive bump comprises copper in one arrangement. The conductive bump is electroplated to the contact, which is a pad coupled to an integrated circuit. The roughened surface of the conductive bump includes cuts interspaced with protrusions. The roughened surface of the conductive bump is formed by etching with a diluted sulfuric peroxide solution. The diluted sulfuric peroxide solution removes 1 μm to 3 μm of material from the sidewall of the conductive bump.

In another arrangement, an integrated circuit device comprises an integrated circuit having a contact and a post directly attached to the contact. The post has a sidewall with a roughened surface. A lead is electrically coupled to the post. A package mold covers portions of the post and the lead. The roughened surface of the conductive bump are configured to interlock with the package mold. An electrically conductive adhesive couples the post to the lead. The post is electroplated to the contact. The roughened surface is created by overetching the post. The roughened surface of the post is formed by etching with a diluted sulfuric peroxide solution. The roughened surface of the conductive bump includes cuts created by the overetching. Etching with the diluted sulfuric peroxide solution removes 1 μm to 3 μm of material from the sidewall of the post.

In a further arrangement, a method for manufacturing an integrated circuit (IC) package comprises providing an IC die having an active surface with at least one contact pad on the active surface, depositing a seed layer on the protective layer and the at least one contact pad, depositing a photoresist film on the seed layer, illuminating the photoresist film with radiation and etching at least one opening in the photoresist film above the at least one contact pad, depositing a metal layer in the at least one opening to form a conductive post, stripping the photoresist layer to expose sidewalls of the conductive post, exposing the conductive post to an extended wet etch process so that the sidewalls of the conductive post have a roughened surface, electrically coupling the conductive post to a leadframe using a conductive solder paste, and encapsulating the IC die, the conductive post, and at least a portion of the leadframe with a mold compound, the mold compound interlocking with the roughened surface on the conductive post to resist delamination. The extended wet etch process uses a diluted sulfuric peroxide solution. The wet etch process removes 1 μm to 3 μm of material from the sidewall of the conductive post. The roughened surface has cuts interspaced with protrusions. The method further comprises applying a protective layer over the active surface of the IC die while leaving the contact pad(s) exposed through the protective layer; and ashing and cleaning the conductive post to remove residue materials.

### BRIEF DESCRIPTION OF THE DRAWINGS

Having thus described the invention in general terms, reference will now be made to the accompanying drawings, wherein:

FIGS. 1A to 1F are schematic cross sections illustrating certain steps in the process flow for completing the fabrication of a conductive bump on a wafer.

FIG. 2A depicts a three-dimensional view of a conductive bump that has been formed on a substrate.

FIG. 2B shows an integrated circuit package in which the sidewalls of a conductive bump have been roughened and then coupled to a leadframe and encapsulated by a mold compound.

FIG. 3A illustrates the crystalline structure on the surface of the conductive bump shown in FIG. 2A.

FIG. 3B illustrates the structure of the surface of the roughened conductive bump after the etching process as shown in FIG. 2B.

FIG. 4A is a cross section view of a copper post.

FIG. 4B is a cross section view of the copper post shown in FIG. 4A after it has been subject to an extended wet etch process using a diluted sulfuric peroxide solution.

FIG. 5 depicts an illustrative method for manufacturing an integrated circuit package having a roughened conductive bump.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

Corresponding numerals and symbols in the different figures generally refer to corresponding parts, unless otherwise indicated. The figures are not necessarily drawn to scale. In the drawings, like reference numerals refer to like elements throughout, and the various features are not necessarily drawn to scale. In the following discussion and in the claims, the terms “including,” “includes,” “having,” “has,” “with,” or variants thereof are intended to be inclusive in a manner similar to the term “comprising,” and thus should be interpreted to mean “including, but not limited to.” Also, the terms “coupled,” “couple,” and/or or “couples” is/are intended to include indirect or direct electrical or mechanical connection or combinations thereof. For example, if a first device couples to or is electrically coupled with a second device that connection may be through a direct electrical connection, or through an indirect electrical connection via one or more intervening devices and/or connections. Elements that are electrically connected with intervening wires or other conductors are considered to be coupled. Terms such as “top,” “bottom,” “front,” “back,” “over,” “above,” “under,” “below,” and such, may be used in this disclosure. These terms should not be construed as limiting the position or orientation of a structure or element but should be used to provide spatial relationship between structures or elements.

The term “semiconductor wafer” is used herein. A semiconductor wafer refers to a thin slice of material, such as crystalline silicon, that is used to fabricate integrated circuits. A large number of integrated circuits may be created on an active surface of the semiconductor wafer. Discrete semiconductor devices can be integrated circuits with hundreds or thousands of transistors coupled to form a functional circuit, for example a microprocessor or memory device. The semiconductor device may also be referred to herein as a semiconductor device or an integrated circuit (IC) die.

The term “semiconductor package” is used herein. A semiconductor package has at least one semiconductor die electrically coupled to terminals and has a package body that protects and covers the semiconductor die. In some arrangements, multiple semiconductor dies can be packaged together. For example, a power metal oxide semiconductor (MOS) field effect transistor (FET) semiconductor device and a second semiconductor device (such as a gate driver die, or a controller die) can be packaged together to form a single packaged electronic device. Additional components such as passive components, such as capacitors, resistors, and inductors or coils, can be included in the packaged electronic device. The semiconductor die is mounted with a package substrate that provides conductive leads. A portion of the conductive leads form the terminals for the packaged device. In wire bonded integrated circuit packages, bond wires couple conductive leads of a package substrate to bond pads on the semiconductor die. The semiconductor die can be mounted to the package substrate with a device side surface facing away from the substrate and a backside surface facing and mounted to a die pad of the package substrate. The semiconductor package can have a package body formed by a thermoset epoxy resin mold compound in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions form the terminals for the semiconductor package. The semiconductor package may also be referred to as a “integrated circuit package,” a “microelectronic device package,” or a “semiconductor device package.”

The term “conductive bump” is used herein. In packaged integrated circuits, conductive bumps, such as copper posts, are formed to provide electrical connection from a lead frame to various contacts or pads on the integrated circuit. In some integrated circuit packages, conductive bumps with a smooth finish are easily delaminated from the mold compound in the packaged integrated circuit. This delamination causes cracks in the polyimide layer and solder near the copper post. This can increase the on-resistance of the conductive bumps. Fabricating the conductive bumps to have a roughened profile mitigates these problems by providing improved mechanical coupling between the conductive bumps to the surrounding mold compound.

The term “rough sidewall” is used herein. When referring to the sidewall of a conductive post, a rough sidewall has an uneven or irregular surface that is not smooth or level. A rough sidewall may also be referred to as bumpy, coarse, craggy, jagged, ragged, rugged, or unpolished. The rough sidewall has cuts (e.g., channels, furrows, gouges, grooves, pits, or trenches) interspaced with protrusions (e.g., ridges, bumps, or projections). In some arrangements, the rough sidewall may be created by removing material from an originally smooth sidewall.

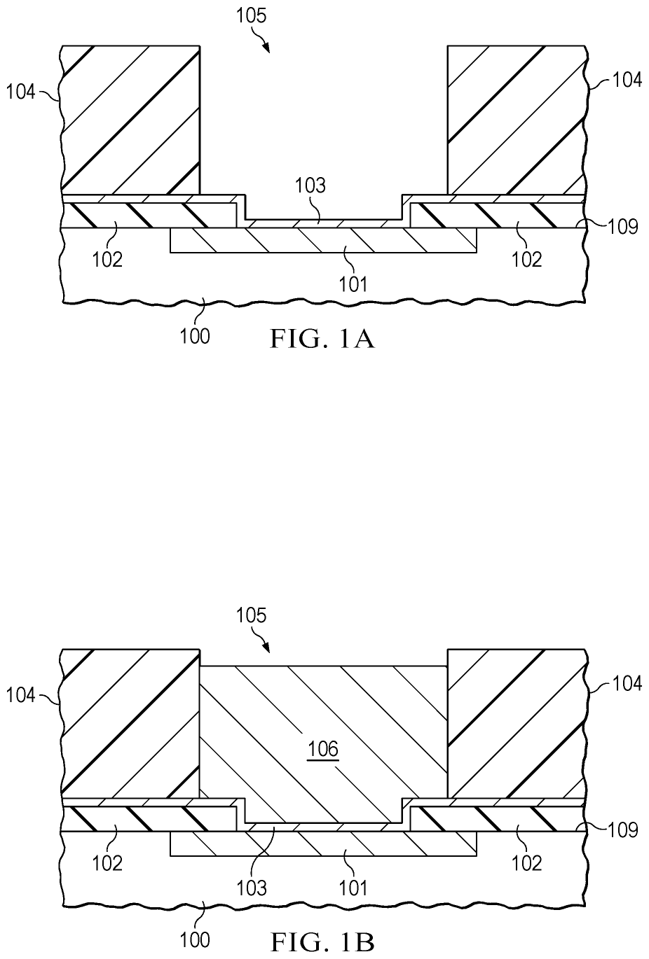

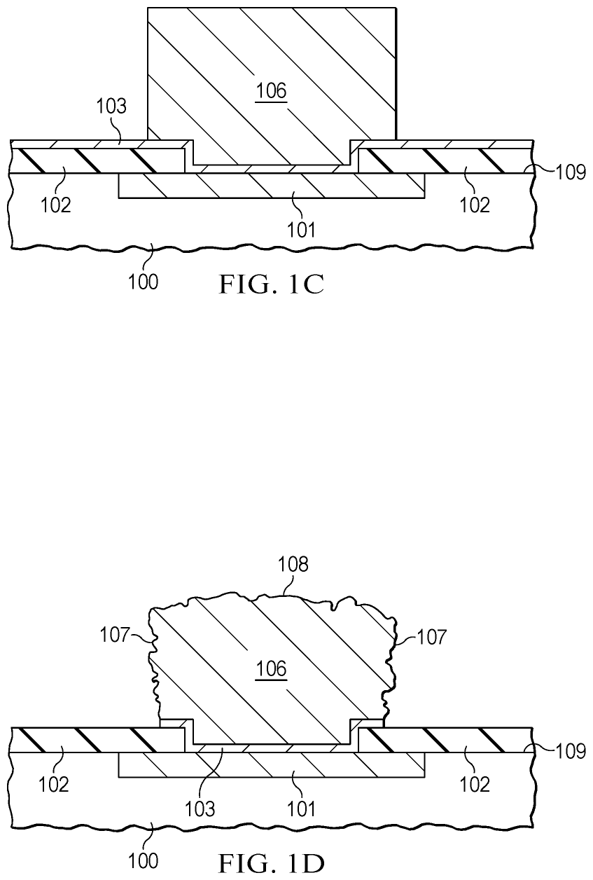

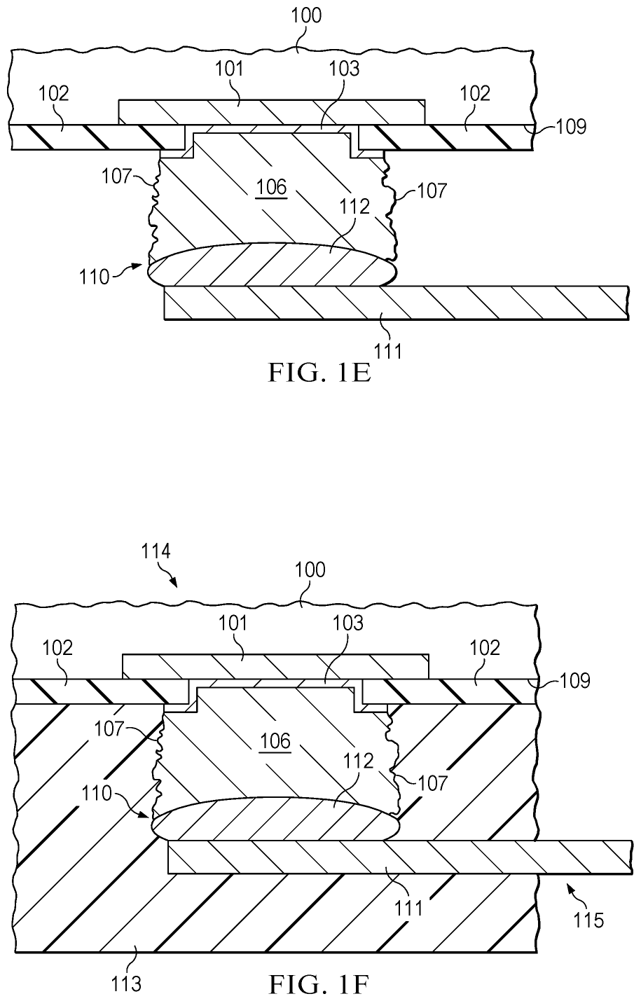

FIGS. 1A to 1F are schematic cross sections illustrating certain steps in the process flow for completing the fabrication of a conductive bump on an integrated circuit (IC) wafer. FIG. 1A shows schematically a portion of a semiconductor wafer, generally designated 100, having contact pads 101 and a protective overcoat 102. The semiconductor material is typically silicon, but may also be silicon germanium, gallium arsenide, or another III-V or II-IV semiconductor. The contact pad 101 is typically copper buy may alternatively be aluminum, an aluminum/copper alloy, or similar materials. The protective overcoat 102 is typically a polymer such as polyimide but may alternatively be silicon nitride, silicon oxynitride, silicon carbide, or silicon dioxide.

A layer 103 of seed metal is deposited to cover the surface of the wafer, such as by a sputtering technique. When the IC metallization is copper, the seed metal may be a copper layer 103 as shown in FIG. 1A. In other arrangements, the seed metal may be a stack of a refractory metal layer, such as titanium/tungsten, and a copper layer. The refractory layer and the copper layer together may form the seed metal layer 103. Other options for layer 103 include one or more refractory metals such as tantalum, titanium, tungsten, molybdenum, chromium, nickel, vanadium, or an alloy of any of these metals. When chip metallization 101 is aluminum or an aluminum alloy, the seed metal may be a stack of a refractory metal/alloy layer (contacting the aluminum) and a copper layer.

A photoresist layer 104 is formed and patterned on seed metal layer 103. The photoresist pattern defines the opening 105, which exposes the seed metal layer 103 over the wafer contact pad 101. The process may include a step of exposing the seed metal layer 103 in the opening 105 to a hydrogen and nitrogen/argon plasma to clean and passivate the seed metal layer 103.

In FIG. 1B, a metal layer 106 is deposited in the photoresist opening 105 onto seed metal layer 103. The metal layer material may be copper. The deposition of metal layer 106 may be accomplished by electrolytic plating or electroless plating.

In FIG. 1C, the photoresist layer 104 has been stripped away to expose metal layer 106. The exposed metal layer 106 functions as a conductive bump or post that is electrically coupled to contact pad 101 and semiconductor wafer 100.

In FIG. 1D, conductive bump 106 has been exposed to a copper etch process, which results in the roughening of the sides 107 and top 108 of conductive bump 106. The etching process may also remove some or all of the exposed seed layer 103 around conductive bump 106. The copper etching process may be a wet etch using a diluted sulfuric peroxide (DSP) solution (for example, 0.15% sulfuric acid (H2SO4) and 0.05% hydrogen peroxide (H2O2)) in a controlled etching chamber. Small portions of the conductive bump 106 are removed in this etching process. For example, 1 to 3 μm of the thickness of surfaces 107, 108 on conductive bump 106 may be removed. The diluted sulfuric peroxide solution creates ridges along the sidewalls 107 of conductive bump 106. This has the effect of increasing the surface area of conductive bump 106. In one arrangement, the length of time for the etching process is performed for twice the typical period, which may be referred to as a double etching. For example, the etching process may be performed for fourteen minutes instead of a seven minute etching process. In other arrangements, different lengths of time may be used to ensure overetching of the conductive bump 106. The etching step may be followed by ashing and cleaning to remove residue materials.

In FIG. 1E, a portion of a flip-chip on leadframe package is shown. The wafer assembly including semiconductor wafer 100 and conductive bump 106 have been flipped upside-down so that the active surface 109 on semiconductor wafer 100 faces down. The distal end 110 of conductive bump 106 is attached to a lead 110 of a leadframe strip using a conductive solder paste 112. This forms a conductive path between lead 111 and contact pad 101 on semiconductor wafer 100.

In FIG. 1F, the semiconductor wafer 100, conductive bump 106, and lead 111 are encapsulated in a mold compound 113 to form an integrated circuit package 114. A portion 115 of the lead 111 protrudes from the mold compound 113 so that the semiconductor wafer 100 can be connected to external devices. The roughened sides 107 of conductive bump 106 provide improved bonding between the mold compound 113 and conductive bump 106. The roughened sides 107 provide increased surface area on conductive bump 106, which provides better adhesion between the mold compound 113 and conductive bump 106. The ridges formed by etching with a diluted sulfuric peroxide solution provide interlocking points between the mold compound 113 and conductive bump 106. This interlocking mitigates the risk of delamination of the mold compound 113 from the sidewall 107 of the conductive bump. Integrated circuit package 114 has reduced stress caused by delamination because mold compound 113 is less likely to detach from roughened conductive bumps 106. As a results, integrated circuit package 114 would have a higher package reliability performance compared to packages without roughened conductive bumps since those packages experience higher levels of delamination.

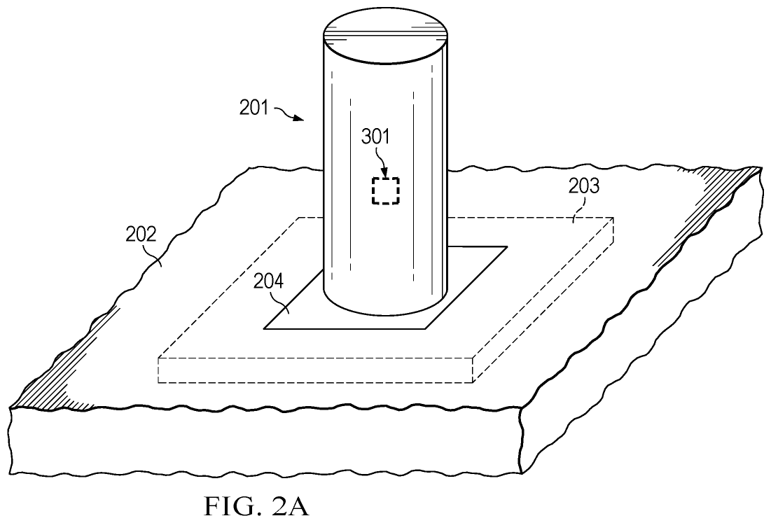

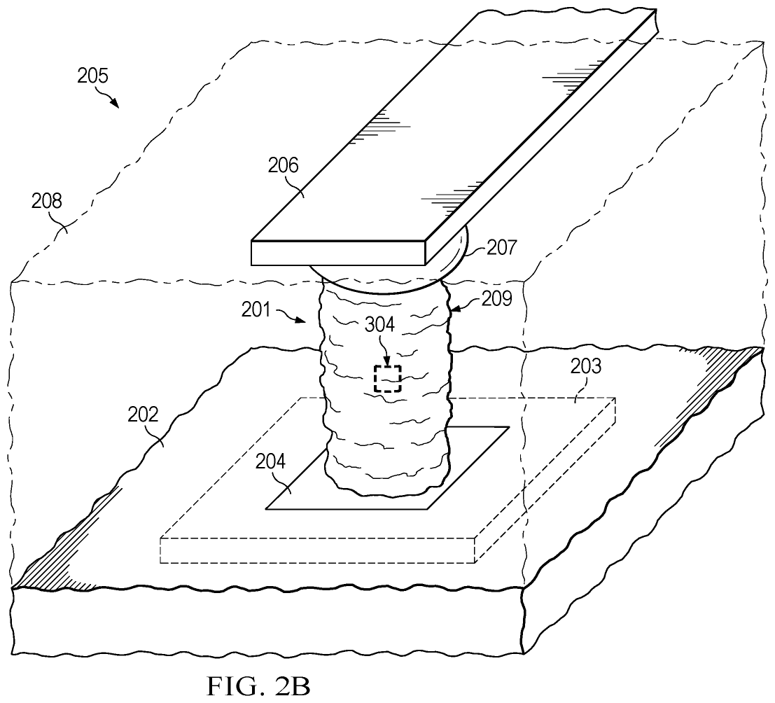

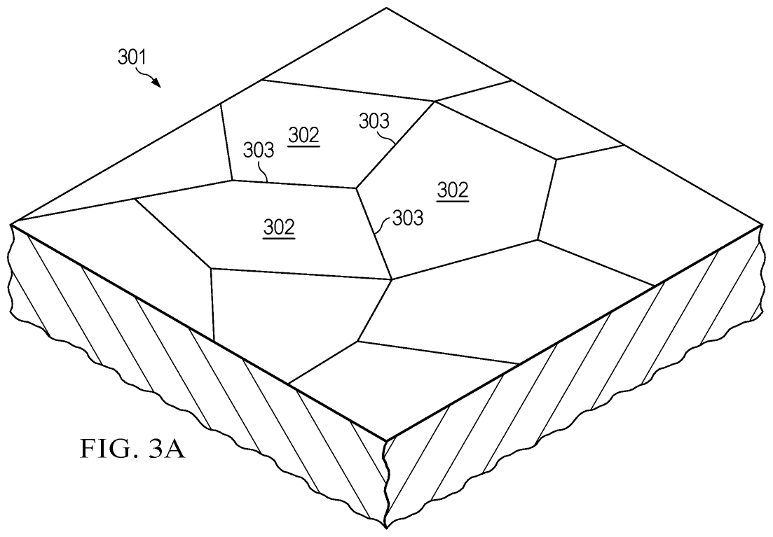

FIG. 2A depicts a three-dimensional view of a conductive bump 201 that has been formed on a substrate 202, such as a silicon substrate. An integrated circuit 203 is formed in the silicon substrate 202 and has a contact 204. The contact 204 can be, for example, a pad or a via electrically coupled to one or more circuit elements (not shown) within the integrated circuit 203. The conductive bump is electrically coupled to the contact 204. In some embodiments, the conductive bump 201 comprises copper and is formed by electroplating a metal (e.g., copper) onto the contact 204 during a semiconductor package manufacturing process.

FIG. 2B shows an integrated circuit package 205 in which the conductive bump 201 has been coupled to a leadframe 206 using an electrically conductive adhesive 207. In practice, the leadframe 206 includes a plurality of leads (not shown) electrically coupled to the integrated circuit 203 by a plurality of additional conductive bumps (not shown). Additionally, a mold compound 208 has been applied and covers substrate 202, integrated circuit 203, contact 204, and the sides 209 of the conductive bump 201. After forming conductive bump 201 on contact 204 as shown in FIG. 2A, additional processing steps are performed. The processing includes overetching conductive bump 201 with a wet etch process using a solution of diluted sulfuric peroxide (DSP). In one arrangement, the DSP solution includes 0.15% H2SO4 and 0.05% H2O2 that is used to etch out copper and to produce a rough sidewall 209 on conductive bump 201.

The overetching of conductive bump 201 increases the surface area on sidewall 209 by creating multiple ridges that project from side of the conductive bump 201 in an approximately perpendicular direction. When the integrated circuit package mold 208 is formed to cover the sidewall 209 of the conductive bump 201, the ridges on the roughened shape of the sidewall 209 interlock with the mold compound 208. This interlocking reduces the risk of the mold compound delaminating from conductive bump 201, which may occur more easily when conductive bump 201 has smooth sidewalls.

The illustrative packaged integrated circuit 205 can be manufactured in several ways to provide the conductive bump 201 having roughened sidewalls 209. In some arrangements, a diluted sulfuric peroxide solution is used for wet etching of the conductive bump. Other methods of manufacture may use other reactants which may be selected based upon the amount of roughening desired, the material used to form the conductive bump, or the time of exposure during etching. For example, copper posts may be etched using diluted concentrations of ammonium hydroxide (NH4OH) and nitric acid (HNO3) solutions, gold posts may be etched using a diluted mixture of nitric acid (HNO3) and hydrochloric acid (HCl), and aluminum posts may be etched using a diluted mixture of phosphoric acid (H3PO4), nitric acid (HNO3) and acetic acid (CH3COOH).

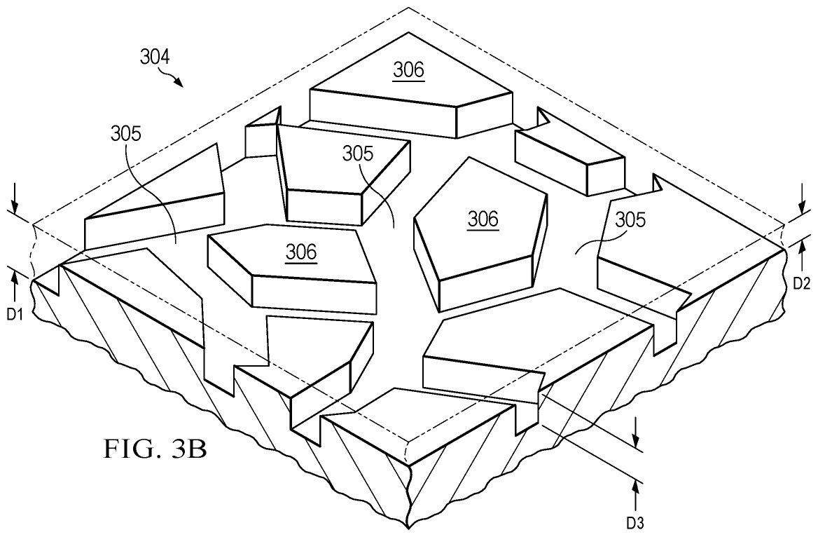

FIG. 3A illustrates the crystalline structure on a surface area 301 of the conductive bump 201 as shown in FIG. 2A. Conductive bump 201 is a copper post in one arrangement. Surface 301 shows the copper grains 302 that form the conductive bump 201. The copper grains 302 are separated by grain boundaries 303. When conductive bump 201 is formed, the copper grains 302 are tightly packed together as shown in FIG. 3A. Etching involves the selective removal of material from surface 301 by chemical means. Etching is a reverse growth process in which surfaces of lowest energy tend to be the most stable and regions of lattice distortion tend to be more susceptible to removal. Etching can be used to reveal the microstructure of surface 301. Etching can also be employed to roughen surface 301 as disclosed herein.

During the chemical etching process, portions of surface 301 are attacked at different rates by the etching chemicals depending upon chemical composition, energy content, and grain orientation of the surface 301. The grain boundaries 303 are attacked at a greater rate than grains 302 due to higher energy content of the grain boundaries. Additionally, the presence of chemically different phases on surface 301 results in variations in the rate of chemical attack. The differences in the rate of chemical attack produce deviations both in angle and depth of certain portions of the etched surface. In one arrangement, etching occurs when a diluted sulfuric peroxide solution is contacted with copper surface 301 because of the difference in rate of attack of the various phases present and their orientation. The etching process is usually accomplished by applying the etching solution to the surface for several seconds to several minutes.

FIG. 3B illustrates the structure on surface area 304 of the roughened conductive bump 201 after the etching process as shown in FIG. 2B. Varying amounts of material have been etched away from the original surface 301. The etching chemicals have attacked the grain boundaries 303 at a faster rate, which removes more material at the grain boundaries 303 than the grains 302. This creates grooves 305 that generally follow the paths of the grain boundaries 303 and raised areas 306 that correspond to the original grains 302. In an etching process using a diluted sulfuric peroxide solution on a copper post, as much as 1.0 μm of material (i.e., depth D1) may be removed from surface 301. The varying etch rates result in less material being removed from the grain surface (i.e., depth D2) compared to the additional amount of material being removed from grain boundaries (i.e., depth D3). The groove depths D3 are 0.1 μm to 0.5 μm in one arrangement. The groove depths range D3 between 0.1 μm to 0.5 μm is advantageous and critical because this particular range minimizes delamination between the mold compound and the copper post. A groove depth less than 0.1 μm is not practical to manufacture using the etching process, and a groove depth more than 0.5 μm is disadvantageous to have proper mold compound flow into the groove and to create interlocking between the copper post and the mold compound.

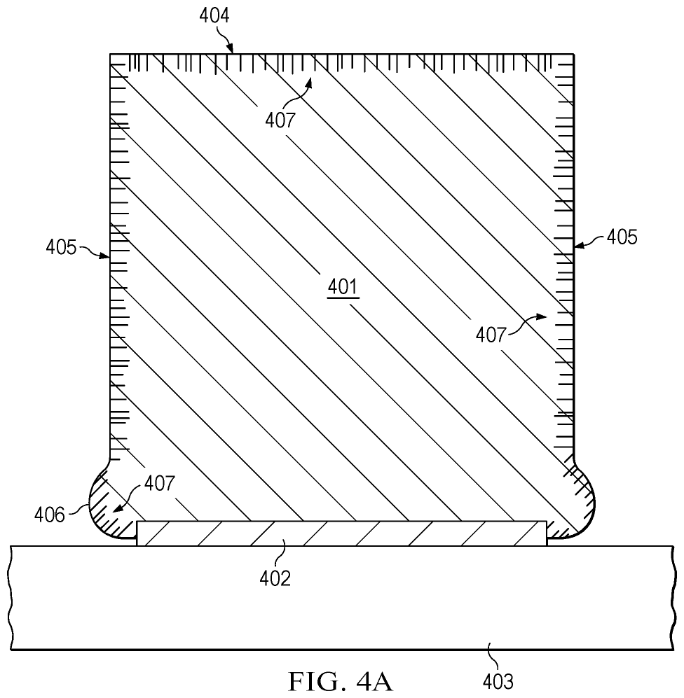

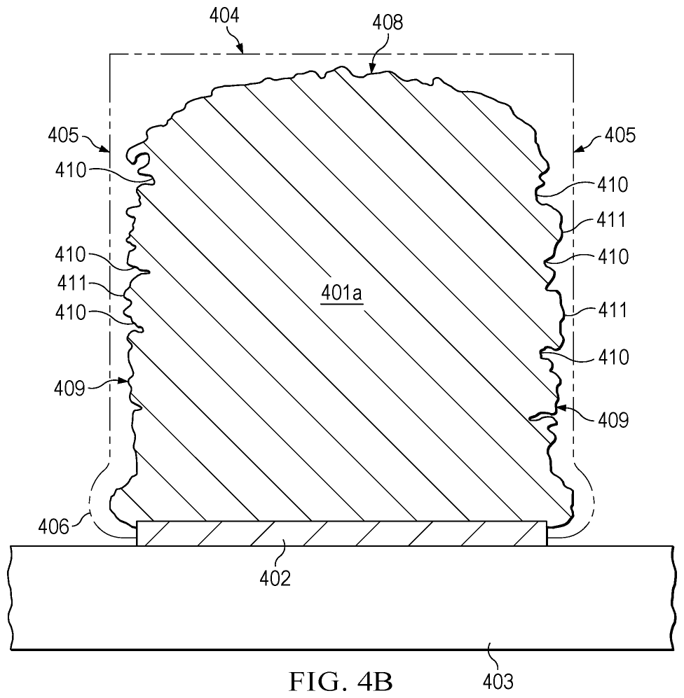

FIG. 4A is a cross section view of a copper post 401 that has been formed on and electrically coupled to contact 402 on a silicon wafer 403. Copper post 401 has a top surface 404 and sidewalls 405. In the illustrated example, a footer 406 has been formed where copper post 401 attaches to contact 402. Footer 406 is also a copper material and is slightly wider than post 401. Copper post 401 has an initial height of approximately 10.0 μm and width of approximately 9.0 μm, with the footer 406 having a width of approximately 11.0 μm. FIG. 4A illustrates the grain boundaries 407 in the copper material along the top surface 404, sidewalls 405, and footer 406. As discussed herein, when a chemical etching solution is applied to copper post 401, the grain boundaries 407 are attacked at a faster rate than the surface of the copper grains.

FIG. 4B is a cross section view of copper post 401a after it has been subject to an extended wet etch process using a diluted sulfuric peroxide solution. Copper material has been etched away from original top surface 404, sidewalls 405, and footer 406. Because the material was removed at different rates, the new top surface 408 and sidewall surface 409 has a roughened texture. In one arrangement, up to 1.0 μm to 3.0 μm of material is removed from the sidewall 405 of a smooth copper post by the corrosive action of the diluted sulfuric peroxide solution. An example etched copper post 401a has height of approximately 9.5 μm and a width varying from approximately 8.1 μm to 8.6 μm with a footer width of approximately 9.7 μm. The faster etching rate at the grain boundaries results in grooved regions 410 on the sidewalls 409 that are etched deeper than the corresponding grain areas 411. This roughened surface provides additional surface area for connection to the mold compound, which minimizes the delamination of the mold compound from post 401a in the final device.

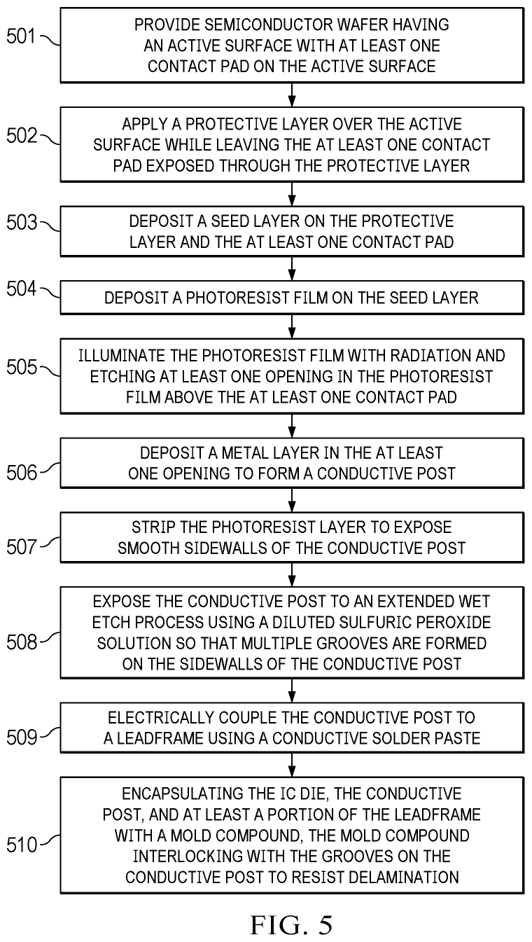

FIG. 5 depicts an illustrative method for manufacturing an integrated circuit package having a roughened conductive bump. In step 501, a semiconductor wafer is provided with an active surface having at least one contact pad on the active surface. In step 502, a protective layer is applied over the active surface while leaving the contact pad(s) exposed through the protective layer. In step 503, a seed layer is deposited on the protective layer and the contact pad(s). In step 504, a photoresist film is deposited on the seed layer. In step 505, the photoresist film is illuminated with radiation to etch at least one opening in the photoresist film above the at least one contact pad. In step 506, a metal layer is deposited in the opening(s) to form a conductive post.

In step 507, the photoresist layer is stripped away to expose relatively smooth sidewalls of the conductive post. In step 508, the conductive post is exposed to an extended wet etch process using a diluted sulfuric peroxide solution so that multiple grooves are formed on the sidewalls of the conductive post. The grooves follow generally along the grain boundaries of the conductive post material. In step 509, electrically coupling the conductive post to a leadframe using a conductive solder paste. In step 510, the IC die, the conductive post, and at least a portion of the leadframe are encapsulated with a mold compound, where the mold compound interlocks with the grooves on the conductive post to resist delamination.

After such processes are completed, the semiconductor wafer, leadframe, and mold compound are severed (“singulated” or “diced”) with a cutting tool, such as a saw or laser, into separate semiconductor packages. Each semiconductor package includes a singulated leadframe, at least one IC die, electrical connections between the die and leadframe (e.g., a roughened conductive bump), and the mold compound which covers at least part of these structures.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. A semiconductor package, comprising:
an integrated circuit having a contact;
a conductive bump directly attached to the contact, the conductive bump having a sidewall with grooves formed by etching a conductive bump material, the grooves having varying depths between 0.1 μm to 0.5 μm;
a leadframe electrically coupled to the conductive bump; and
an integrated circuit package mold covering portions of the conductive bump and the lead frame, the grooves in the sidewall of the conductive bump configured to interlock with the integrated circuit package mold.

2. The semiconductor package of claim 1, further comprising:
an electrically conductive adhesive coupling the conductive bump to the lead frame.

3. The semiconductor package of claim 1, wherein the conductive bump comprises copper.

4. The semiconductor package of claim 1, wherein the conductive bump is electroplated to the contact.

5. The semiconductor package of claim 1, wherein the contact is a pad coupled to an integrated circuit.

6. The semiconductor package of claim 1, wherein the grooves are formed by etching along grain boundaries of the conductive bump material.

7. The semiconductor package of claim 1, wherein the grooves are formed by etching with a diluted sulfuric peroxide solution.

8. The semiconductor package of claim 7, wherein etching with the diluted sulfuric peroxide solution removes 1 μm to 3 μm of material from the sidewall of the conductive bump.

9. An integrated circuit device, comprising:
an integrated circuit having a contact;
a post directly attached to the contact, the post having a sidewall with grooves formed by etching a post material, the grooves having varying depths between 0.1 μm to 0.5 μm;
a lead electrically coupled to the post; and
a package mold covering portions of the post and the lead, the grooves in the sidewall of the conductive bump configured to interlock with the package mold.

10. The integrated circuit device of claim 9, further comprising:
an electrically conductive adhesive coupling the post to the lead.

11. The integrated circuit device of claim 9, wherein the post is electroplated to the contact.

12. The integrated circuit device of claim 9, wherein the grooves are created by overetching the post.

13. The integrated circuit device of claim 12, wherein the grooves are formed along grain boundaries on an exterior of the post material.

14. The integrated circuit device of claim 12, wherein the grooves are formed by etching with a diluted sulfuric peroxide solution.

15. The integrated circuit device of claim 14, wherein etching with the diluted sulfuric peroxide solution removes 1 μm to 3 μm of material from the sidewall of the post.

16. A method for manufacturing an integrated circuit (IC) package, comprising:
providing an IC die having an active surface with at least one contact pad on the active surface;
depositing a seed layer on the protective layer and the at least one contact pad;
depositing a photoresist film on the seed layer;
illuminating the photoresist film with radiation and etching at least one opening in the photoresist film above the at least one contact pad;
depositing a metal layer in the at least one opening to form a conductive post;
stripping the photoresist layer to expose sidewalls of the conductive post;
exposing the conductive post to an extended wet etch process so that material is removed from the sidewalls of the conductive post to create grooves along grain boundaries of the metal layer, the grooves having varying depths between 0.1 μm to 0.5 μm;
electrically coupling the conductive post to a leadframe using a conductive solder paste; and
encapsulating the IC die, the conductive post, and at least a portion of the leadframe with a mold compound, the mold compound interlocking with the grooves on the conductive post to resist delamination.

17. The method of claim 16, wherein the extended wet etch process uses a diluted sulfuric peroxide solution.

18. The method of claim 16, wherein the wet etch process removes 1 μm to 3 μm of material from the sidewall of the conductive post.

19. The method of claim 16, wherein the grooves are interspaced with grains of the metal layer.

20. The method of claim 13, further comprising:
applying a protective layer over the active surface of the IC die while leaving the at least one contact pad exposed through the protective layer; and
ashing and cleaning the conductive post to remove residue materials.
